(19) United States
(12) Patent Application Publication
(10) Pub. No.: US 2025/0181478 A1
(43) Pub. Date: Jun. 5, 2025

(54) MULTI-CORE PARALLEL SIMULATION METHOD AND PLATFORM ARCHITECTURE FOR IMPLEMENTING MULTI-CORE PARALLEL SIMULATION

(71) Applicant: Jinan Xinyu Software Technology Co., Ltd., Jinan, Shandong (CN)

(72) Inventors: Min Yi, Jinan, Shandong (CN); Yunzhao Yang, Jinan, Shandong (CN); Min Cheng, Jinan, Shandong (CN); Chuanqiang Shen, Jinan, Shandong (CN); Ming Wei, Jinan, Shandong (CN); Tianhao Yi, Jinan, Shandong (CN)

(21) Appl. No.: 18/726,413

(22) PCT Filed: Apr. 14, 2023
(86) PCT No.: PCT/CN2023/088282

§ 371 Date: Jul. 3, 2024

(30) Foreign Application Priority Data
Aug. 8, 2022 (CN) 202210941533.4

(51) Int. Cl. G06F 11/3604

(52) U.S. Cl. CPC G06F 11/3604

(57) ABSTRACT

The present disclosure discloses a multi-core parallel simulation method and a platform architecture for implementing multi-core parallel simulation, and relates to the field of chip simulation technologies. The simulation method includes: dividing a chip simulation task into two parts based on design code and verification code, to obtain a design code simulation task and a verification code simulation task; separately executing the design code simulation task and the verification code simulation task on different CPU cores; and further allocating the verification code simulation task to a plurality of CPU cores for execution, and executing simulation tasks among the CPU cores in a multithreaded parallel manner. The simulation method further includes: converting design code in the design code simulation task into verification code to obtain converted verification code; and allocating the converted verification code to a new CPU core for execution.

### CROSS-REFERENCE TO RELATED APPLICATION

This application claims the benefit of Chinese Patent Application No. 202210941533.4, filed on Aug. 8, 2022, which is hereby incorporated by reference in its entirety including any tables, figures, or drawings.

### TECHNICAL FIELD

The present disclosure relates to the field of chip simulation technologies, and in particular, to a multi-core parallel simulation method and a platform architecture for implementing multi-core parallel simulation.

### BACKGROUND

In a chip-simulation verification platform, there are two parts of content: design code+verification code. One part is chip design code compiled in the Verilog or SystemVerilog language. This part of code may be synthesized into hardware of a chip for chip manufacturing. The other part is the verification code compiled in another language. This part of code cannot be synthesized, is not used for chip manufacturing, and is only used for chip verification. The another language is SystemVerilog/C++/Python or the like.

The two parts of code need to be executed on a high-performance server, where execution time occupied by the first part, namely, the design code, is between 30% and 90%, and execution time occupied by the second part, namely, the verification code, is between 10% and 70%.

As a size of the chip increases, sizes of the two parts of code become large. Simulation execution consumes a large amount of time. Based on different sizes, simulation execution time ranges from several minutes to more than ten days. Therefore, improving simulation efficiency and shortening simulation time are long-standing and difficult problems in the chip industry.

There are two directions for resolving the problem: One is software simulation acceleration, and the other is hardware simulation acceleration. The two acceleration solutions are developed and complementary to each other, but do not replace each other.

An existing software simulation acceleration solution is as follows:

To improve simulation efficiency and shorten simulation time, in the industry, task segmentation is performed for the Verilog design code and the verification code that are mixed together, and an attempt is made to allocate tasks, obtained through segmentation, to a plurality of CPU cores for execution, to implement simulation acceleration. A desired acceleration factor is about 10 times. In a specific design scenario, a theoretical acceleration factor can be reached. In a general scenario, an actual acceleration factor is only 1.2 times to 1.5 times. However, the existing software simulation acceleration solution has limited efficiency improvement, and is actually an abandoned solution that is no longer developed.

That is, in the existing software simulation technical solution, the “design code” and the “verification code” are mixed together. This is based on a characteristic of a chip simulation service, making it difficult to segment the “design code” and the “verification code”. However, behavior characteristics of the “design code” and the “verification code” are different from each other greatly. The “design code” describes behavior of hardware, and the “verification code” describes behavior of software. In the existing solution, a simulation task is segmented based on the characteristic of the “design code” instead of an essential difference between the “design code” and the “verification code”. The segmentation work of the simulation task is limited by a “verification code” task, and the “verification code” cannot be effectively segmented. In addition, the “design code” varies greatly, and although an automated tool completes effective task segmentation, the key is the tool cannot effectively reduce association between tasks.

Performing segmentation by using the tool is to segment both the “design code” and the “verification code” as “design code”. After the tool completes the segmentation work, tasks obtained through segmentation are run on a plurality of CPU cores for execution, and the tasks obtained through segmentation are tens of thousands, hundreds of thousands, or even millions of tasks. The plurality of CPU cores are 2 to 64 CPU cores. The “design code” is segmented to obtain small but numerous tasks. The “verification code” is segmented to obtain large but few tasks. The large tasks obtained by segmenting the “verification code” finally determine an acceleration effect, and a reason is that data needs to be exchanged for these tasks, and synchronization thereof requires mutual waiting, which consumes time and limits the acceleration effect.

Only when a quantity of threads is equal to a quantity of CPU cores, acceleration can be implemented. In the foregoing existing software simulation technical solution, a quantity of thread tasks obtained through segmentation is far greater than a quantity of available CPU cores. There are inevitably thousands of tasks executed on one core. These thread tasks are executed in a time division manner. As a result, there are time consumption overheads during thread switching, and a partial acceleration effect is offset.

### SUMMARY

A technical problem to be resolved in the present disclosure is that a software simulation technical solution in chip-simulation verification has a problem of a slow simulation speed and low efficiency. An objective is to provide a multi-core parallel simulation method and a platform architecture for implementing multi-core parallel simulation. The method in the present disclosure is an improved software simulation acceleration solution, and is based on a PVM (Parallel Verification Methodology) parallel verification methodology, so that multi-core parallel verification is implemented, and simulation acceleration is performed, to improve a chip-simulation verification speed and efficiency.

The present disclosure is implemented by the following technical solutions:

According to a first aspect, the present disclosure provides a multi-core parallel simulation method, where the simulation method includes:
dividing a chip simulation task into two parts based on a difference between design code and verification code, to obtain a design code simulation task and a verification code simulation task;
separately executing the design code simulation task and the verification code simulation task on different CPU cores; and
further allocating the verification code simulation task to a plurality of CPU cores for multithreaded parallel execution.

The present disclosure focuses on researching a software simulation acceleration solution, and proposes a concept based on a PVM (Parallel Verification Methodology) parallel verification methodology, so that multi-core parallel verification is implemented, and simulation acceleration is performed, to improve a chip-simulation verification speed and efficiency. In the present disclosure, first, the verification code and the design code are considered differently by using a manual method, and the verification code and the design code are divided as a whole into two parts: the design code simulation task and the verification code simulation task. Then, the design code simulation task and the verification code simulation task are separately executed on different CPU cores, so that a large overall chip simulation task can be divided into two parts to a maximum degree. Because the verification code and the Verilog design code belong to different technical fields, different technologies and implementation solutions may be used for the verification code and the Verilog design code. In this case, through division into two parts, simulation acceleration technologies of the two code can be developed separately. In a previous technical method, there is no such an idea basis, and the two types of code are mixed together and are interlinked, making it impossible to independently develop the simulation acceleration technology. In the present disclosure, through division into two parts, a task of improving simulation efficiency of the design code is simplified, which provides a possibility for subsequent technology development. In addition, the verification code simulation task is further allocated to a plurality of CPU cores for execution.

Further, the simulation method further includes:
converting design code in the design code simulation task into verification code to obtain converted verification code; and
allocating the converted verification code to a new CPU core for execution.

In the entire chip simulation task, execution time occupied by the design code is between 30% and 90%, and execution time occupied by the verification platform code is between 10% and 70%. Therefore, in the foregoing technical solution, simulation time of the design code is shortened by reducing a size of the design code.

Further, the further allocating the verification code simulation task to a plurality of CPU cores for multithreaded parallel execution includes:
dividing the verification code simulation task into a plurality of verification code simulation subtasks; and
allocating the plurality of verification code simulation subtasks to a plurality of corresponding CPU cores, and executing the plurality of verification code simulation subtasks in a multi-CPU core and multithreaded parallel manner, where
the multi-CPU core and multithreaded parallel manner means performing multithreaded parallel execution among a plurality of CPU cores.

A plurality of threads in the multithreaded parallel include several threads, and several thread instances are executed on different CPU cores.

Further, simulation execution of the design code simulation task and the plurality of verification code simulation subtasks is implemented by separately executing different verification components in different threads, and asynchronous communication is performed between the verification components by using communication pipelines.

According to a second aspect, the present disclosure further provides a platform architecture for implementing multi-core parallel simulation, where the platform architecture includes a design simulation module and a verification simulation module;
the design simulation module is configured to: run Verilog design code, and execute a design code simulation task; and
the verification simulation module is configured to: allocate a verification code simulation task to a plurality of CPU cores, and execute the verification code simulation task in a multi-CPU core and multithreaded parallel manner.

Further, the platform architecture further includes a verification platform monitoring module, configured to: verify management of the platform architecture, and monitor execution of simulation tasks of threads on different CPU cores.

Further, the platform architecture further includes a code conversion module, configured to convert design code in the design code simulation task into verification code to obtain converted verification code; and
the verification simulation module is further configured to allocate the converted verification code to a new CPU core for execution.

Further, the verification simulation module includes:
a subtask division unit, configured to divide the verification code simulation task into a plurality of verification code simulation subtasks; and
a task simulation running unit, configured to: allocate the plurality of verification code simulation subtasks to a plurality of corresponding CPU cores, and execute the plurality of verification code simulation subtasks in a multi-CPU core and multithreaded parallel manner, where
the multi-CPU core and multithreaded parallel manner means performing multithreaded parallel execution among a plurality of CPU cores.

Further, simulation execution of the design code simulation task and the plurality of verification code simulation subtasks is implemented by separately executing different verification components in different threads, and asynchronous communication is performed between the verification components by using communication pipelines.

Further, the threads include eight types of threads: a simulation main thread, a verification platform main thread, a reference model thread, a memory model thread, a driver software thread, an excitation thread, a result comparison thread, and a simulation model thread;
the verification components include twelve types of verification components: a system model component, a behavioral reference model component, an IP simulation model component, a register component, a software engine component, a scorecard component, a function coverage component, a random excitation component, a traffic scheduling component, a comparator component, a bus functional model component, and a fault injection component; and
an allocation relationship between the verification components and the threads is as follows:
the bus functional model component is executed in the simulation main thread;
the system model component, the behavioral reference model component, the scorecard component, and the function coverage component are executed in the reference model thread;
the register component and the function coverage component are executed in the memory model thread;
the software engine component is executed in the driver software thread;
the function coverage component, the random excitation component, the traffic scheduling component, and the fault injection component are executed in the excitation thread;
the function coverage component and the comparator component are executed in the result comparison thread; and
the IP simulation model component and the function coverage component are executed in the simulation model thread.

Further, the communication pipelines include a first communication channel between the random excitation component and the bus functional model component, a second communication channel between the random excitation component and the behavioral reference model component, a third communication channel between the comparator component and the bus functional model component, a fourth communication channel between the comparator component and the behavioral reference model component, a fifth communication channel between the software engine component and the bus functional model component, a sixth communication channel between the software engine component and the register component, a seventh communication channel between the behavioral reference model component and the register component, an eighth communication channel between the register component and the bus functional model component, and a ninth communication channel between the IP simulation model component and the bus functional model component.

Further, data exchange of the communication pipeline is in a form of a data packet, which effectively reduces data exchange frequency, and helps improve efficiency.

Compared with the conventional technology, the present disclosure has the following advantages and beneficial effects:

1. In the present disclosure, the verification code and the design code are divided as a whole, and are executed on different CPU cores, so that a large simulation task can be divided into two parts to a maximum degree. Because the verification platform code and the Verilog design code belong to different technical fields, different technologies and implementation solutions may be used for the verification platform code and the Verilog design code. In this case, through division into two parts, simulation acceleration technologies of the two code can be developed separately. In a previous technical method, there is no such an idea basis, and the two types of code are mixed together and are interlinked, making it impossible to independently develop the simulation acceleration technology.

2. In the present disclosure, the verification platform is divided into twelve verification components that are separately executed in eight different threads, which increases simulation parallelism of the verification platform, and more helps reduce simulation time. The reduced simulation time ranges from 20% to 80%, that is, an acceleration effect is 1.25 times to 5 times, which depends on a ratio between the execution time of the design code and the execution time of the verification code.

3. In the present disclosure, for the platform architecture, a flat structure is used instead of a hierarchical and class-encapsulated form similar to UVM, which reduces association and coupling between the verification components, and helps the verification components independently develop without being interlinked.

4. In the present disclosure, efficient communication pipelines are used between the threads of the verification components, thereby reducing communication time and waiting time between the threads.

5. In the present disclosure, an IP module in the Verilog design code is replaced with an IP simulation model that is executed on a separate CPU core. In this way, simulation time of the design code can be greatly reduced. Specifically, 80% to 95% of time can be reduced. In the industry, there is a concept and practice of the IP “simulation model”, but there is no concept and mechanism for parallel execution of the simulation model.

### BRIEF DESCRIPTION OF DRAWINGS

The accompanying drawing described herein is used to provide further understanding of embodiments of the present disclosure, and constitutes a part of the present application, but does not constitute limitations to the embodiments of the present disclosure. In the accompanying drawings:

FIG. 1 is a flowchart of a multi-core parallel simulation method according to the present disclosure;

FIG. 2 is a schematic structural diagram of a platform architecture for implementing multi-core parallel simulation according to the present disclosure; and

FIG. 3 is a schematic diagram of distribution of a communication pipeline in a platform architecture for implementing multi-core parallel simulation according to the present disclosure.

### DESCRIPTION OF EMBODIMENTS

To make the objectives, technical solutions and advantages of the present disclosure clearer, the present disclosure is further described in detail below with reference to embodiments and the accompanying drawing. The schematic implementations of the present disclosure and descriptions thereof are only used to explain the present disclosure, but are not intended to limit the present disclosure.

### Embodiment 1

The present disclosure focuses on researching a software simulation acceleration solution, and proposes a concept based on a PVM (Parallel Verification Methodology) parallel verification methodology, so that multi-core parallel verification is implemented, and simulation acceleration is performed, to improve a chip-simulation verification speed and efficiency. In the present disclosure, first, verification code and design code are considered differently by using a manual method, and the verification code and the design code are divided as a whole into two parts: a design code simulation task and a verification code simulation task. Then, the design code simulation task and the verification code simulation task are separately executed on different CPU cores, so that a large overall chip simulation task can be divided into two parts to a maximum degree. Because the verification code and the Verilog design code belong to different technical fields, different technologies and implementation solutions may be used for the verification code and the Verilog design code. In this case, through division into two parts, simulation acceleration technologies of the two code can be developed separately. In a previous technical method, there is no such an idea basis, and the two types of code are mixed together and are interlinked, making it impossible to independently develop the simulation acceleration technology. In the present disclosure, through division into two parts, a task of improving simulation efficiency of the design code is simplified, which provides a possibility for subsequent technology development. In addition, the verification code simulation task is further allocated to a plurality of CPU cores for execution.

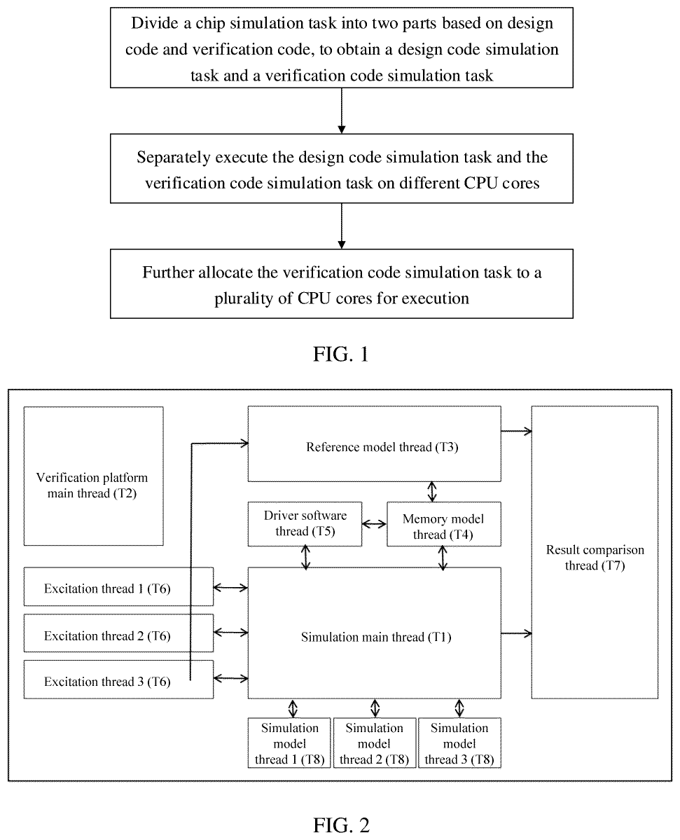

FIG. 1 is a flowchart of a multi-core parallel simulation method according to the present disclosure. The present disclosure provides a multi-core parallel simulation method, and the simulation method includes:
dividing a chip simulation task into two parts based on a difference between design code and verification code, to obtain a design code simulation task and a verification code simulation task;
separately executing the design code simulation task and the verification code simulation task on different CPU cores; and
further allocating the verification code simulation task to a plurality of CPU cores for multithreaded parallel execution.

In a further implementation, the simulation task is executed among the foregoing CPU cores in a multithreaded parallel manner.

In a further implementation, the simulation method further includes:
converting design code in the design code simulation task into verification code to obtain converted verification code; and
allocating the converted verification code to a new CPU core for execution.

In the entire chip simulation task, execution time occupied by the design code is between 30% and 90%, and execution time occupied by the verification platform code is between 10% and 70%. Therefore, in the foregoing technical solution, simulation time of the design code is shortened by reducing a size of the design code.

In a further implementation, the further allocating the verification code simulation task to a plurality of CPU cores for multithreaded parallel execution includes:
dividing the verification code simulation task into a plurality of verification code simulation subtasks; and
allocating the plurality of verification code simulation subtasks to a plurality of corresponding CPU cores, and executing the plurality of verification code simulation subtasks in a multi-CPU core and multithreaded parallel manner, where
the multi-CPU core and multithreaded parallel manner means performing multithreaded parallel execution among a plurality of CPU cores.

A plurality of threads in the multithreaded parallel include several threads, and several thread instances are executed on different CPU cores.

In a further implementation, simulation execution of the design code simulation task and the plurality of verification code simulation subtasks is implemented by separately executing different verification components in different threads, and asynchronous communication is performed between the verification components by using communication pipelines.

### Embodiment 2

FIG. 2 is a schematic structural diagram of a platform architecture for implementing multi-core parallel simulation according to the present disclosure. A difference between this embodiment and Embodiment 1 is as follows: This embodiment provides a platform architecture for implementing multi-core parallel simulation, and the platform architecture includes a design simulation module and a verification simulation module;
the design simulation module is configured to: run Verilog design code, and execute a design code simulation task; and
the verification simulation module is configured to: allocate a verification code simulation task to a plurality of CPU cores, and execute the verification code simulation task in a multi-CPU core and multithreaded parallel manner.

In a further implementation, the design simulation module and the verification simulation module execute simulation tasks on different CPU cores in a multi-CPU core and multithreaded parallel manner.

In a further implementation, the platform architecture further includes a code conversion module, configured to convert design code in the design code simulation task into verification code to obtain converted verification code; and
the verification simulation module is further configured to allocate the converted verification code to a new CPU core for execution.

In the entire chip simulation task, execution time occupied by the design code is between 30% and 90%, and execution time occupied by the verification platform code is between 10% and 70%. Therefore, in the foregoing technical solution, most of design code of IP is converted into verification code, and transferred to another CPU core for running, to implement a parallel simulation mechanism. In this way, simulation time of the design code is shortened by reducing a size of the design code by the code conversion module.

The platform architecture further includes a verification platform monitoring module, configured to: verify management of the platform architecture, and monitor execution of simulation tasks of threads on different CPU cores.

In a further implementation, the verification simulation module includes:
a subtask division unit, configured to divide the verification code simulation task into a plurality of verification code simulation subtasks; and
a task simulation running unit, configured to: allocate the plurality of verification code simulation subtasks to a plurality of corresponding CPU cores, and execute the plurality of verification code simulation subtasks in a multi-CPU core and multithreaded parallel manner, where
the multi-CPU core and multithreaded parallel manner means performing multithreaded parallel execution among a plurality of CPU cores.

In a further implementation, simulation execution of the design code simulation task and the plurality of verification code simulation subtasks is implemented by separately executing different verification components in different threads, and asynchronous communication is performed between the verification components by using communication pipelines.

In a specific implementation, in the platform architecture, the design code and the verification code are separately executed in eight types of threads (T1 to T8). The design code is executed in a thread simThreadT1, and the part of converted verification code converted from the design code is executed in a thread dmThreadT8. The verification code is separately executed in threads T3 to T7, and the thread T2 is used to verify management of the platform architecture, and monitor execution of simulation tasks of threads on different CPU cores.

The foregoing eight types of threads (T1 to T8) and more than eight thread instances are all executed on different CPU cores, so that a large chip simulation task is allocated to different CPU cores for execution, and a multi-core parallel execution effect is implemented, thereby achieving a software simulation acceleration effect.

In the present disclosure, the “verification code” is divided into eight types of threads, and an interconnection relationship between various types of threads is defined. It's not important if there arefewer or more types of threads, provided that a quantity of threads ranges from a dozen to several dozens, which is comparable to a quantity of CPU cores in a high-performance server from 2 to 64. The threads are divided as follows:

1. A simulation main thread simThread (T1) is a main thread of a simulator (sim:simulator), and is used to run the Verilog design code.

2. A verification platform main thread sysThread (T2) is used for system management (sys:system) and monitoring of the verification platform.

3. A reference model thread brmThread (T3) is used to run a behavioral reference model BRM (Behavioral Reference Model).

4. A memory model thread memThread (T4) is used to run a memory (mem:memory) model in design under verification DUV (Design Under Verification) and BRM.

5. A driver software thread softwareThread (T5) is used to run driver software of DUV, and is used for chip configuration, data processing, and the like.

6. An excitation thread txThread (T6) is used to construct and transmit (tx: transmit) random excitation data.

7. A result comparison thread rxThread (T7) is used to receive (rx: receive) result data and expected data, and compare whether the result data is consistent with the expected data.

8. A simulation model thread dmThread (T8) is used to run an IP (Intellectual Property) simulation model (dm: donut model).

There may be a plurality of threads for each of the foregoing T4, T5, T6, and T8 types, and there can be only one thread for each of the foregoing T2, T3, and T7 types.

In the present disclosure, the verification code is further divided into a plurality of verification components VCs. In the present disclosure, there are twelve types of verification components VCs that are allocated to the foregoing eight types of threads for execution, to further improve execution efficiency of the verification code.

In the platform architecture for implementing multi-core parallel simulation in the present disclosure, there are the following twelve types of verification components (Verification Components), VC1 to VC12. The verification components are executed in different threads. An allocation relationship between the verification components and the execution threads is shown in the following Table 1:

TABLE 1
Allocation relationship table

| Verification component | Execution thread |
|---|---|
| VC1: System model component | T3 |
| VC2: Behavioral reference model component | T3 |
| VC3: IP simulation model component | T8 |
| VC4: Register component | T4 |
| VC5: Software engine component | T5 |
| VC6: Scorecard component | T3 |
| VC7: Function coverage component | T3, T4, T6, T7, T8 |
| VC8: Random excitation component | T6 |
| VC9: Traffic scheduling component | T6 |
| VC10: Comparator component | T7 |
| VC11: Bus functional model component | T1 |
| VC12: Fault injection component | T6 |

Specifically, the verification components in the present disclosure perform asynchronous communication by using the following nine types of communication pipelines:
C1: a first communication channel between the random excitation component VC8 and the bus functional model component VC11;
C2: a second communication channel between the random excitation component VC8 and the behavioral reference model component VC2;
C3: a third communication channel between the comparator component VC10 and the bus functional model component VC11;
C4: a fourth communication channel between the comparator component VC10 and the behavioral reference model component VC2;
C5: a fifth communication channel between the software engine component VC5 and the bus functional model component VC11;
C6: a sixth communication channel between the software engine component VC5 and the register component VC4;
C7: a seventh communication channel between the behavioral reference model component VC2 and the register component VC4;
C8: an eighth communication channel between the register component VC4 and the bus functional model component VC11; and
C9: a ninth communication channel between the IP simulation model component VC3 and the bus functional model component VC11.

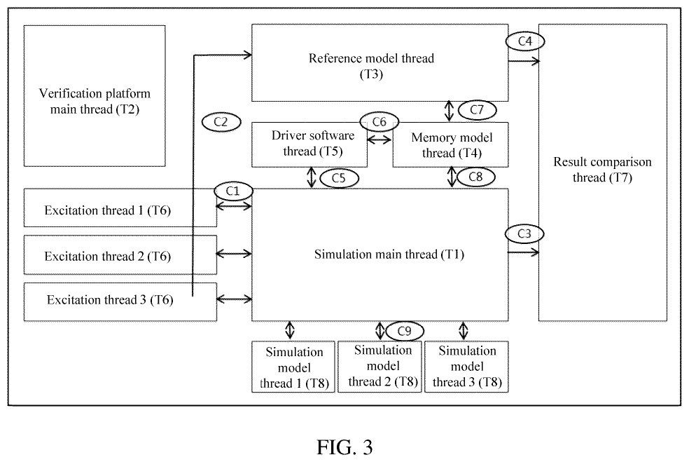

Distribution of the foregoing nine types of communication pipelines is shown in FIG. 3.

Synchronization between the plurality of threads and communication efficiency of the communication pipeline determine simulation efficiency of the entire verification platform. Only when the threads do not wait for each other, and run at respective maximum speeds, it can be ensured that simulation efficiency is improved.

Data exchanged in the communication pipelines is a data packet, and the data packet is a set of a plurality of types of data, which can reduce data exchange frequency of the communication pipeline, and effectively ensure simulation efficiency.

A quantity of thread types, a quantity of verification components, and a quantity of communication pipelines may be adjusted based on actual situations.

The present disclosure has the following technical advantages:

1. In the present disclosure, the verification code and the design code are divided as a whole, and are executed on different CPU cores, so that a large simulation task can be divided into two parts to a maximum degree. Because the verification platform code and the Verilog design code belong to different technical fields, different technologies and implementation solutions may be used for the verification platform code and the Verilog design code. In this case, through division into two parts, simulation acceleration technologies of the two code can be developed separately. In a previous technical method, there is no such an idea basis, and the two types of code are mixed together and are interlinked, making it impossible to independently develop the simulation acceleration technology.

2. In the present disclosure, the verification platform is divided into twelve verification components that are separately executed in eight different threads, which increases simulation parallelism of the verification platform, and more helps reduce simulation time. The reduced simulation time ranges from 20% to 80%, that is, an acceleration effect is 1.25 times to 5 times, which depends on a ratio between the execution time of the design code and the execution time of the verification code.

3. In the present disclosure, for the platform architecture, a flat structure is used instead of a hierarchical and class-encapsulated form similar to UVM, which reduces association and coupling between the verification components, and helps the verification components independently develop without being interlinked.

4. In the present disclosure, efficient communication pipelines are used between the threads of the verification components, thereby reducing communication time and waiting time between the threads.

5. In the present disclosure, an IP module in the Verilog design code is replaced with an IP simulation model that is executed on a separate CPU core. In this way, simulation time of the design code can be greatly reduced. Specifically, 80% to 95% of time can be reduced. In the industry, there is a concept and practice of the IP “simulation model”, but there is no concept and mechanism for parallel execution of the simulation model.

The objectives, technical solutions, and beneficial effects of the present disclosure are further described in detail in the above specific implementations. It should be understood that the above described are only specific implementations of the present disclosure and are not intended to limit the protection scope of the present disclosure. Any modification, equivalent replacement, improvement, and the like made within the spirit and principle of the present disclosure should fall within the protection scope of the present disclosure.

1. A multi-core parallel simulation method, wherein the simulation method comprises:
dividing a chip simulation task into two parts based on design code and verification code, to obtain a design code simulation task and a verification code simulation task;
separately executing the design code simulation task and the verification code simulation task on different CPU cores; and
further allocating the verification code simulation task to a plurality of CPU cores for multithreaded parallel execution.

2. The multi-core parallel simulation method according to claim 1, wherein the simulation method further comprises:
converting design code in the design code simulation task into verification code to obtain converted verification code; and
allocating the converted verification code to a new CPU core for execution.

3. The multi-core parallel simulation method according to claim 1, wherein the further allocating the verification code simulation task to a plurality of CPU cores for multithreaded parallel execution comprises:
dividing the verification code simulation task into a plurality of verification code simulation subtasks; and
allocating the plurality of verification code simulation subtasks to a plurality of corresponding CPU cores, and executing the plurality of verification code simulation subtasks in a multi-CPU core and multithreaded parallel manner, wherein
the multi-CPU core and multithreaded parallel manner means performing multithreaded parallel execution among a plurality of CPU cores.

4. A platform architecture for implementing multi-core parallel simulation by using the multi-core parallel simulation method according to claim 1, wherein the platform architecture comprises a design simulation module and a verification simulation module;
the design simulation module is configured to: run Verilog design code, and execute a design code simulation task; and
the verification simulation module is configured to: allocate a verification code simulation task to a plurality of CPU cores, and execute the verification code simulation task in a multi-CPU core and multithreaded parallel manner.

5. The platform architecture for implementing multi-core parallel simulation according to claim 4, wherein the platform architecture further comprises a verification platform monitoring module, configured to: verify management of the platform architecture, and monitor execution of simulation tasks of threads on different CPU cores.

6. The platform architecture for implementing multi-core parallel simulation according to claim 4, wherein the platform architecture further comprises a code conversion module, configured to convert design code in the design code simulation task into verification code to obtain converted verification code; and
the verification simulation module is further configured to allocate the converted verification code to a new CPU core for execution.

7. The platform architecture for implementing multi-core parallel simulation according to claim 4, wherein the verification simulation module comprises:
a subtask division unit, configured to divide the verification code simulation task into a plurality of verification code simulation subtasks; and
a task simulation running unit, configured to: allocate the plurality of verification code simulation subtasks to a plurality of corresponding CPU cores, and execute the plurality of verification code simulation subtasks in a multi-CPU core and multithreaded parallel manner, wherein
the multi-CPU core and multithreaded parallel manner means performing multithreaded parallel execution among a plurality of CPU cores.

8. The platform architecture for implementing multi-core parallel simulation according to claim 7, wherein simulation execution of the design code simulation task and the plurality of verification code simulation subtasks is implemented by separately executing different verification components in different threads, and asynchronous communication is performed between the verification components by using communication pipelines.

9. The platform architecture for implementing multi-core parallel simulation according to claim 8, wherein the threads comprise eight types of threads: a simulation main thread, a verification platform main thread, a reference model thread, a memory model thread, a driver software thread, an excitation thread, a result comparison thread, and a simulation model thread;
the verification components comprise twelve types of verification components: a system model component, a behavioral reference model component, an IP simulation model component, a register component, a software engine component, a scorecard component, a function coverage component, a random excitation component, a traffic scheduling component, a comparator component, a bus functional model component, and a fault injection component; and
an allocation relationship between the verification components and the threads is as follows:
the bus functional model component is executed in the simulation main thread;
the system model component, the behavioral reference model component, the scorecard component, and the function coverage component are executed in the reference model thread;
the register component and the function coverage component are executed in the memory model thread;
the software engine component is executed in the driver software thread;
the function coverage component, the random excitation component, the traffic scheduling component, and the fault injection component are executed in the excitation thread;
the function coverage component and the comparator component are executed in the result comparison thread; and
the IP simulation model component and the function coverage component are executed in the simulation model thread.

10. The platform architecture for implementing multi-core parallel simulation according to claim 9, wherein the communication pipelines comprise a first communication channel between the random excitation component and the bus functional model component, a second communication channel between the random excitation component and the behavioral reference model component, a third communication channel between the comparator component and the bus functional model component, a fourth communication channel between the comparator component and the behavioral reference model component, a fifth communication channel between the software engine component and the bus functional model component, a sixth communication channel between the software engine component and the register component, a seventh communication channel between the behavioral reference model component and the register component, an eighth communication channel between the register component and the bus functional model component, and a ninth communication channel between the IP simulation model component and the bus functional model component.

11. The platform architecture for implementing multi-core parallel simulation according to claim 10, wherein data exchange of the communication pipeline is performed in a form of a data packet.
